(19) United States
(12) Patent Application Publication
(10) Pub. No.: US 2025/0176373 A1
(43) Pub. Date: May 29, 2025

(54) DISPLAY PANEL AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Kai YU, Beijing (CN); Yongliang ZHAO, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/843,310

(22) PCT Filed: Oct. 25, 2023
(86) PCT No.: PCT/CN2023/126546

§ 371 Date: Sep. 3, 2024

(30) Foreign Application Priority Data
Nov. 24, 2022 (CN) 202211486448.X

(51) Int. Cl. H10K 59/124; H10K 59/121; H10K 59/131; H10K 59/35

(52) U.S. Cl. CPC H10K 59/124; H10K 59/131; H10K 59/1213; H10K 59/353

(57) ABSTRACT

A display panel includes a display region, at least one hole-opening region, and a hole-edge region between a hole-opening region and the display region. The hole-edge region surrounds the hole-opening region, and includes a wiring region and an encapsulation region arranged along a first direction, the first direction being a direction from the display region to the hole-opening region. The display panel further includes a substrate, and a first semiconductor layer and at least one silicon nitride layer arranged in stack on the substrate in sequence. The display panel is provided therein with a plurality of first exhaust holes in the encapsulation region, each first exhaust hole penetrates through each silicon nitride layer, and extends to the first semiconductor layer from a side of the display panel opposite the substrate.

### CROSS-REFERENCE TO RELATED APPLICATIONS

This application is a national phase entry under 35 USC 371 of International Patent Application No. PCT/CN2023/126546, filed on Oct. 25, 2023, which claims priority to Chinese Patent Application No. 202211486448.X, filed on Nov. 24, 2022, which are incorporated herein by reference in their entirety.

### TECHNICAL FIELD

The present disclosure relates to the field of display technologies, and in particular, to a display panel and a display apparatus.

### BACKGROUND

With the rapid development of display technologies, display apparatuses have gradually come throughout people's lives. Among them, organic light-emitting diodes (OLEDs) are widely used in smart products such as mobile phones, televisions, and notebook computers owing to their advantages of self-luminescence, low power consumption, wide viewing angle, fast response speed, high contrast, and flexible display.

### SUMMARY

In one aspect, a display panel is provided. The display panel includes: a display region, at least one hole-opening region, and a hole-edge region between a hole-opening region in the at least one hole-opening region and the display region, the hole-edge region surrounding the hole-opening region. The hole-edge region includes: a wiring region and an encapsulation region arranged in sequence along a first direction, the first direction being a direction from the display region to the hole-opening region. The display panel further includes: a substrate, and a first semiconductor layer and at least one silicon nitride layer that are arranged in a stack on the substrate in sequence. The display panel is provided therein with a plurality of first exhaust holes in the encapsulation region, each first exhaust hole in the plurality of first exhaust holes penetrates through each silicon nitride layer in the at least one silicon nitride layer, and each first exhaust hole in the plurality of first exhaust holes extends to the first semiconductor layer from a side of the display panel opposite the substrate.

In some embodiments, the plurality of first exhaust holes are arranged at intervals around the hole-opening region.

In some embodiments, an arrangement density of the plurality of first exhaust holes gradually decreases along the first direction.

In some embodiments, in a direction perpendicular to the first direction, there is a first distance between two adjacent first exhaust holes in the plurality of first exhaust holes; and in the direction perpendicular to the first direction, there is a second distance between another two adjacent first exhaust holes in the plurality of first exhaust holes further away from the hole-opening region as compared to the two adjacent first exhaust holes, where the first distance is greater than the second distance.

In some embodiments, a cross-section of the first exhaust hole is in a shape of any one of a rectangle, a triangle, a pentagon, a hexagon, and a circle, a plane where the cross-section is located being parallel to a plane where the substrate is located.

In some embodiments, the display panel further includes: a first gate insulating layer, a second gate insulating layer, a first inorganic insulating layer, a second inorganic insulating layer, a third gate insulating layer, an interlayer dielectric layer, and a passivation layer that are disposed on a side of the first semiconductor layer away from the substrate. The at least one silicon nitride layer includes: the second gate insulating layer, the first inorganic insulating layer and the passivation layer; and the first exhaust hole penetrates through the passivation layer, the interlayer dielectric layer, the third gate insulating layer, the second inorganic insulating layer, the first inorganic insulating layer, the second gate insulating layer, and the first gate insulating layer.

In some embodiments, the display panel further includes: a second semiconductor layer disposed between the second inorganic insulating layer and the third gate insulating layer, in the wiring region. The display panel is provided therein with a plurality of second exhaust holes in the wiring region, and each second exhaust hole in the plurality of second exhaust holes extends to the second semiconductor layer from the side of the display panel opposite the substrate.

In some embodiments, the second exhaust hole penetrates through the passivation layer, the interlayer dielectric layer and the third gate insulating layer.

In some embodiments, the display panel is provided therein with a plurality of third exhaust holes in the wiring region, each third exhaust hole in the plurality of third exhaust holes penetrates through each silicon nitride layer in the at least one silicon nitride layer, and each third exhaust hole in the plurality of third exhaust holes extends to the first semiconductor layer from the side of the display panel opposite the substrate.

In some embodiments, the display panel includes: the first exhaust hole, and further includes a second exhaust hole and a third exhaust hole, and the first exhaust hole, the second exhaust hole and the third exhaust hole each have a size in a range of 0.5 μm to 3 μm.

In some embodiments, the display panel further includes: a plurality of pixel driving circuits and a plurality of light-emitting devices. A pixel driving circuit in the plurality of pixel driving circuits is used to drive a light-emitting device in the plurality of light-emitting devices to emit light, the plurality of pixel driving circuits each include a second light-emitting control transistor, and the first semiconductor layer includes a first electrode zone and a second electrode zone of the second light-emitting control transistor.

The display panel further includes: a first gate conductive layer disposed on a side of the first semiconductor layer away from the substrate. The first gate conductive layer includes: a plurality of light-emitting control signal lines and a gate pattern of the second light-emitting control transistor, and the gate pattern of the second light-emitting control transistor is electrically connected to a light-emitting control signal line in the plurality of light-emitting control signal lines.

The display panel further includes: a first source-drain metal layer disposed on a side of the first gate conductive layer away from the substrate, where the first source-drain metal layer includes a plurality of first patterns, and a first pattern in the plurality of first patterns is electrically connected to the second electrode zone of the second light-emitting control transistor. The display panel further includes: an anode layer disposed on a side of the first source-drain metal layer away from the substrate, where the anode layer includes anode patterns of the plurality of light-emitting devices, and the first pattern is electrically connected to an anode pattern of a light-emitting device in the plurality of light-emitting devices. A ratio of an overlapping area of an orthographic projection of the first pattern on the substrate and an orthographic projection of the light-emitting control signal line on the substrate to an area of the orthographic projection of the first pattern on the substrate is greater than 10%.

In some embodiments, the ratio of the overlapping area of the orthographic projection of the first pattern on the substrate and the orthographic projection of the light-emitting control signal line on the substrate to the area of the orthographic projection of the first pattern on the substrate is 25%.

In some embodiments, the display panel further includes: a second source-drain metal layer disposed on a side of the first semiconductor layer away from the substrate, and a transfer electrode layer disposed between the second source-drain metal layer and the anode layer. The transfer electrode layer includes a plurality of transfer electrodes, where the pixel driving circuit is electrically connected to the anode pattern through a transfer electrode in the plurality of transfer electrodes.

In some embodiments, the display panel further includes: a plurality of light-emitting devices, the plurality of light-emitting devices including: a plurality of red light-emitting devices, a plurality of green light-emitting devices and a plurality of blue light-emitting devices. The display panel further includes: a second source-drain metal layer disposed on a side of the first semiconductor layer away from the substrate, where the second source-drain metal layer includes: a plurality of data signal lines and a plurality of power supply signal lines, and the plurality of data signal lines and the plurality of power supply signal lines each extend in a second direction. Every two data signal lines in the plurality of data signal lines are arranged alternately with every two power supply signal lines in the plurality of power supply signal lines along a third direction, the second direction intersecting the third direction.

In the plurality of data signal lines and the plurality of power supply signal lines, a power supply signal line, a data signal line, another data signal line, and another power supply signal line are arranged in sequence in the third direction as a signal line group. The display panel further includes: an anode layer disposed on a side of the second source-drain metal layer away from the substrate. The anode layer includes: a third anode pattern of each blue light-emitting device in the plurality of blue light-emitting devices, and an orthographic projection of the third anode pattern on the substrate overlaps with an orthographic projection of the signal line group on the substrate.

In some embodiments, the anode layer further includes: a first anode pattern of each red light-emitting device in the plurality of red light-emitting devices and a second anode pattern of each green light-emitting device in the plurality of green light-emitting devices. A ratio of an area of an orthographic projection of the first anode pattern on the substrate, an area of an orthographic projection of the second anode pattern on the substrate, and an area of an orthographic projection of the third anode pattern on the substrate is 30:21:70. A ratio of an overlapping area of orthographic projections of the first anode pattern and the second source-drain metal layer on the substrate, an overlapping area of orthographic projections of the second anode pattern and the second source-drain metal layer on the substrate, and an overlapping area of orthographic projections of the third anode pattern and the second source-drain metal layer on the substrate is 14:11:27.

In some embodiments, the second source-drain metal layer further includes: a plurality of second patterns connected between two adjacent power supply signal lines in two adjacent signal line groups, and the orthographic projection of the second anode pattern on the substrate overlaps with an orthographic projection of a second pattern in the plurality of second patterns on the substrate.

In some embodiments, the orthographic projection of the first anode pattern on the substrate overlaps with the orthographic projection of the signal line group on the substrate.

In some embodiments, the first anode pattern and the third anode pattern are arranged alternately in the third direction.

In some embodiments, the display panel further includes a plurality of pixel driving circuits, each pixel driving circuit in the plurality of pixel driving circuits including: multiple transistors and a capacitor, the multiple transistors including: a first reset transistor, a compensation transistor, a driving transistor, a data writing transistor, a first light-emitting control transistor, a second light-emitting control transistor, and a second reset transistor.

The first reset transistor and the compensation transistor each include an oxide thin film transistor; and the driving transistor, the data writing transistor, the first light-emitting control transistor, the second light-emitting control transistor, and the second reset transistor each include a low temperature polycrystalline silicon thin film transistor.

In another aspect, a display apparatus is provided. The display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel provided in accordance with some embodiments;

FIG. 2 is an enlarged diagram of the region B of the display panel provided in accordance with FIG. 1;

FIG. 3 is a cross-sectional structural diagram of the display panel provided in accordance with in FIG. 2 obtained along the section line CC;

FIG. 4 is a structural diagram of a display panel provided in accordance with some embodiments of the present disclosure;

FIG. 5 is a cross-sectional structural diagram of the display panel provided in accordance with FIG. 4 obtained along the section line DD;

FIG. 6 is an enlarged diagram of the region E of the display panel provided in accordance with FIG. 4;

FIG. 7 is a structural diagram of a pixel driving circuit provided in accordance with some embodiments of the present disclosure;

FIG. 8 is a diagram showing a process of charging a fourth node of a pixel driving circuit provided in accordance with some embodiments of the present disclosure;

FIG. 9 is a cross-sectional structural diagram of a display panel provided in accordance with some embodiments of the present disclosure;

FIG. 10A is a structural diagram of a first semiconductor layer, a first gate conductive layer, a second gate conductive layer, a second semiconductor layer, a third gate conductive layer, and a first source-drain metal layer after being stacked in accordance with some embodiments of the present disclosure;

FIG. 10B is a structural diagram of a first semiconductor layer, a first gate conductive layer, a second gate conductive layer, a second semiconductor layer, a third gate conductive layer, and a first source-drain metal layer after being stacked in accordance with some embodiments;

FIG. 11 is a structural diagram of a first semiconductor layer and a first gate conductive layer after being stacked in accordance with some embodiments of the present disclosure;

FIG. 12 is a structural diagram of a first semiconductor layer, a first gate conductive layer, and a second gate conductive layer after being stacked in accordance with some embodiments of the present disclosure;

FIG. 13 is a structural diagram of a first semiconductor layer, a first gate conductive layer, a second gate conductive layer, a second semiconductor layer, and a third gate conductive layer after being stacked in accordance with some embodiments of the present disclosure;

FIG. 14 is a structural diagram of a second source-drain metal layer, a transfer electrode layer, and an anode layer after being stacked in accordance with some embodiments of the present disclosure;

FIG. 15 is a structural diagram of a second source-drain metal layer and an anode layer after being stacked in accordance with some embodiments of the present disclosure;

FIG. 16 is a structural diagram of a second source-drain metal layer, a transfer electrode layer, and an anode layer after being stacked in accordance with some embodiments;

FIG. 17 is a structural view of a second source-drain metal layer and an anode layer after being stacked in accordance with some embodiments; and

FIG. 18 is a structural diagram of a display apparatus provided in accordance with some embodiments of the present disclosure.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure.

Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the terms such as “coupled” and “connected” and derivatives thereof may be used. For example, the term “connected” may represent a fixed connection, or a detachable connection, or a one-piece connection, alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

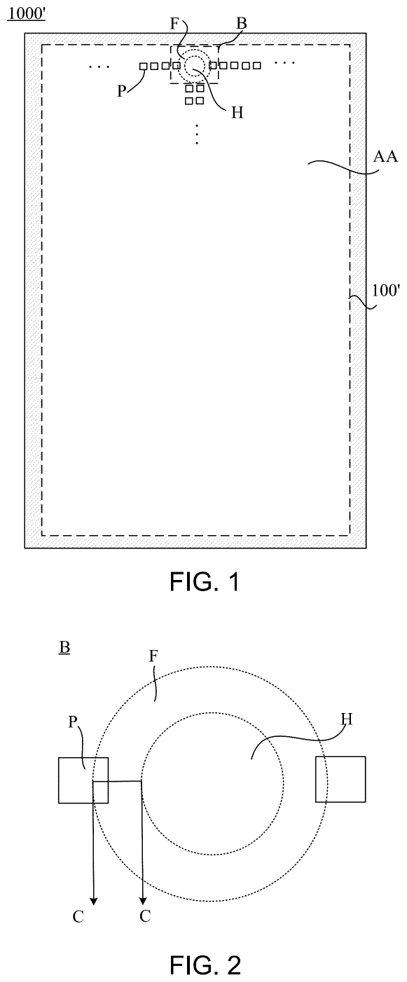

As shown in FIG. 1, the display apparatus 1000′ includes a display panel 100′. A display region (Active Area, AA) of the display panel 100′ is provided with a plurality of pixels P in an array, and the plurality of pixels P emit light for realizing image display. Here, uneven display at low grayscale brightness is a pressing focus of the image quality problem during the display process.

For example, for a display brightness of 2 nits (Nit) and 32 Gray (Grayscale), a current at this display brightness is less than 50 pA (Picoampere). Due to the relatively low display brightness, it is more likely to cause problems of uneven image display at this display brightness.

It will be noted that the grayscale refers to the grade of hue shades of the electromagnetic wave radiation intensity of a ground object represented on a black and white image, and is a scale that divides the spectral characteristics of the ground object. Nit is the unit of brightness, where brightness is a physical quantity indicating the intensity of the surface luminescence (reflection) of a luminophor (reflector).

In the related art, the design of the pixels P in the display region AA of the display panel 100′ is improved in order to solve the problem of low grayscale brightness unevenness.

In general, as shown in FIG. 1, the display apparatus 1000′ further includes other electronic elements, such as a camera, the display region AA of the display panel 100′ is generally provided therein with a hole-opening region H, and an electronic element is disposed in a hole of the hole-opening region H.

In order to ensure that the provision of the hole-opening region H does not affect the display of the display panel 100′, as shown in FIG. 1 and FIG. 2, the hole-opening region H and the display region AA will be provided therebetween with a hole-edge region F, so that a certain distance exists between the pixels P and the hole-opening region H, which serves as a preset distance. The presence of this preset distance prevents the provision of the hole-opening region H from causing an influence on the image display quality.

However, when the design of the pixels P in the display region AA of the display panel 100′ is improved in order to solve the problem of uneven display at low grayscale brightness, there will exist a situation causing the pixels P to approach the hole of the hole-opening region H. As a result, the distance between the pixels P and the hole-opening region H is less than the preset distance, thereby affecting the quality of the image display. Examples of improvements made to the design of the pixels P in the display region AA of the display panel 100′ can be found in subsequent contents and will not be described in detail here.

One of the reasons why the pixels P proximate to the hole of the hole-opening region H affects the quality of the image display is as follows.

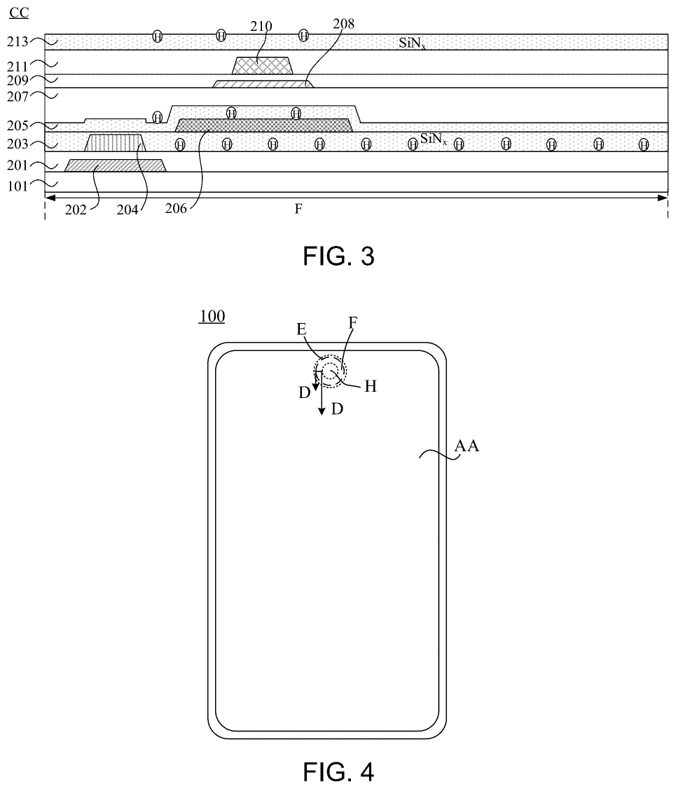

In a film layer structure of the display panel 100′, as shown in FIG. 3, multiple inorganic film layers are arranged in a stack in the hole-edge region F, which includes a silicon nitride (SiNₓ) inorganic film layer, and a high temperature process is required during the film formation of the inorganic film layer. Since there exists a large amount of hydrogen (H) in the silicon nitride (SiNₓ) inorganic film layer, and the hydrogen (H) exists in the form of silicon-hydrogen bond (Si—H) in the silicon nitride (SiNₓ) inorganic film layer, the silicon-hydrogen bond (Si—H) will break at the high temperature to generate hydrogen gas (H₂), resulting in the presence of hydrogen gas (H₂) in the silicon nitride (SiNₓ) inorganic film layer. If the pixels P are proximate to the hole-opening region H, the large amount of hydrogen gas (H₂) that exists in the hole-edge region F will cause bright spots to appear in the hole-edge region F, resulting in uneven brightness of the display panel 100′.

In light of this, as shown in FIG. 4, some embodiments of the present disclosure provide a display panel 100. The display panel 100 includes: a display region AA, at least one hole-opening region H, and a hole-edge region F located between a hole-opening region H and the display region AA, and the hole-edge region F surrounds the hole-opening region H.

In some examples, referring to FIG. 4 again, the display panel 100 includes a hole-opening region H, and a shape of the hole-opening region H is, for example, a circle. A region between the hole-opening region H and the display region AA is a hole-edge region F. The hole-edge region F surrounds the hole-opening region H, which means that the hole-edge region F is provided around the hole-opening region H in a loop. The display region AA surrounds the hole-edge region F and the hole-opening region H. There may be multiple hole-opening regions H, and each hole-opening region H is provided with a hole-edge region F surrounding the outside thereof. The number of the hole-opening regions H is set as needed and is not limited here.

For example, a hole in the hole-opening region H is used to accommodate other electronic elements, such as a camera.

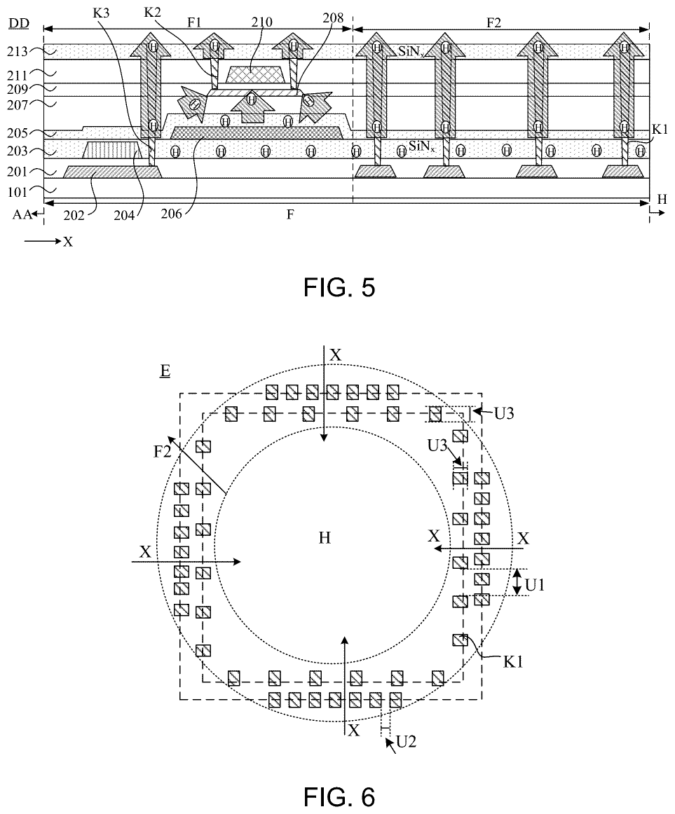

As shown in FIG. 5, the hole-edge region F includes: a wiring region F1 and an encapsulation region F2 arranged in sequence along a first direction X, where the first direction X is a direction from the display region AA to the hole-opening region H. The display panel 100 further includes: a substrate 101, and a first semiconductor layer 202 and at least one silicon nitride layer that are arranged in a stack on the substrate 101 in sequence. Here, the display panel 100 is provided therein with a plurality of first exhaust holes K1 in the encapsulation region F2. Each first exhaust hole K1 in the plurality of first exhaust holes K1 penetrates through each silicon nitride layer in the at least one silicon nitride layer, and each first exhaust hole K1 in the plurality of first exhaust holes K1 extends to the first semiconductor layer 202 from a side of the display panel 100 opposite the substrate 101.

For example, the substrate 101 may be a flexible substrate. Flexible substrates may include a film substrate and a plastic substrate, where the film substrate includes a polymeric organic material. The substrate 101 may be a rigid substrate, where the rigid substrate may be any one of a glass substrate, a quartz substrate, a glass ceramic substrate, and a crystallized glass substrate.

For example, the display panel 100 includes a plurality of inorganic film layers, and the plurality of inorganic film layers include the at least one silicon nitride layer, where the silicon nitride layer refers to an inorganic film layer including a silicon nitride material.

For example, as shown in FIG. 5, the plurality of inorganic film layers include a first gate insulating layer 201, a second gate insulating layer 203, a first inorganic insulating layer 205, a second inorganic insulating layer 207, a third gate insulating layer 209, an interlayer dielectric layer 211, and a passivation layer 213 that are disposed on a side of the first semiconductor layer 202 away from the substrate 101, in which the at least one silicon nitride layer includes: the second gate insulating layer 203, the first inorganic insulating layer 205 and the passivation layer 213.

In this case, the first exhaust hole K1 penetrates through the passivation layer 213, the interlayer dielectric layer 211, the third gate insulating layer 209, the second inorganic insulating layer 207, the first inorganic insulating layer 205, the second gate insulating layer 203, and the first gate insulating layer 201.

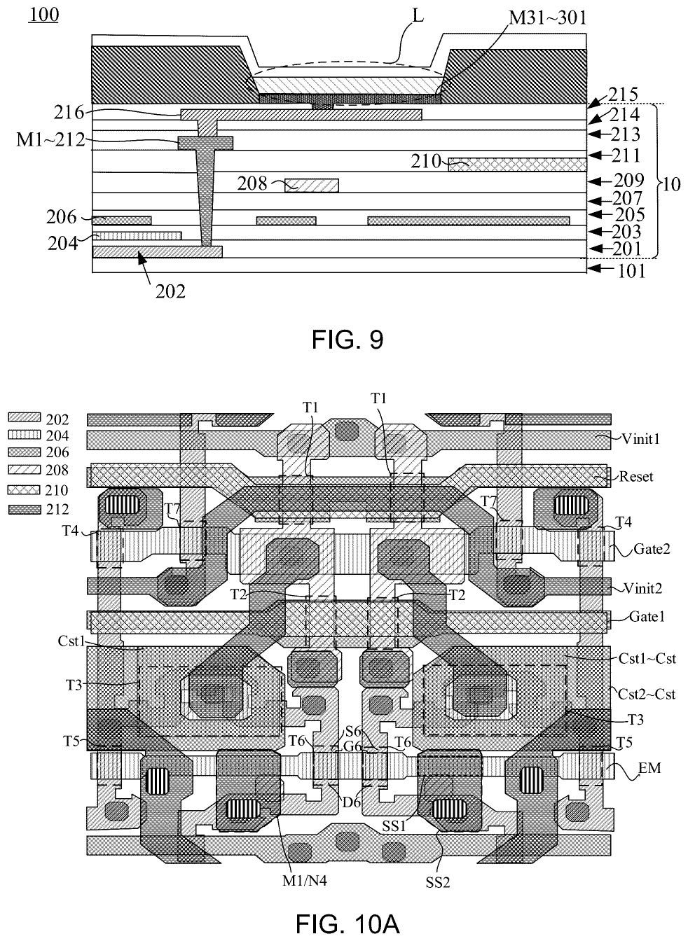

It will be noted that as shown in FIG. 5, a side of the passivation layer 213 away from the substrate 101 may further be provided with a first planarization layer 214 (as shown in FIG. 9), a second planarization layer 215 (as shown in FIG. 9), an inorganic encapsulation layer, an organic encapsulation layer, and the like, which are not limited herein. The first exhaust hole K1 also penetrates through other film layers on the side of the passivation layer 213 away from the substrate 101, ensuring that the hydrogen gas entering the first exhaust hole K1 may be discharged smoothly.

By the provision of the first exhaust hole K1, and making the first exhaust hole K1 penetrate through all silicon nitride layers in the inorganic film layers, a large amount of hydrogen gas existing in the silicon nitride layer may be discharged out of the display panel 100. When the pixels P are designed and adjusted to be proximate to the hole-opening region H, bright spots may be prevented from appearing in the hole-edge region F, thereby solving the problem of uneven brightness in the hole-edge region F of the display panel 100.

In some embodiments, as shown in FIG. 6, the plurality of first exhaust holes K1 are arranged at intervals around the hole-opening region H.

For example, as shown in FIG. 6, the plurality of first exhaust holes K1 are arranged around the hole-opening region H in a loop shape. For example, the loop shape may be a rectangle, or the loop shape may also be a circle, which is not limited here.

The hydrogen gas in the silicon nitride layer may be effectively discharged through the plurality of first exhaust holes K1 arranged around the hole-opening region H in a loop shape, thereby ensuring the exhaust effect of the hydrogen gas and preventing the existence of hydrogen gas from affecting the image quality of the display panel 100.

In some embodiments, as shown in FIG. 6, an arrangement density of the first exhaust holes K1 gradually decreases along the first direction X.

For example, as shown in FIG. 6, proximate to the hole-opening region H, the first exhaust holes K1 have a relatively small arrangement density. For example, in a direction perpendicular to the first direction X, a distance U1 between two adjacent first exhaust holes K1 is relatively large. Relatively away from hole-opening region H, the first exhaust holes K1 have a relatively large arrangement density. For example, in the direction perpendicular to the first direction X, a distance U2 between two adjacent first exhaust holes K1 is relatively small. That is, U1 is greater than U2 (U1>U2).

The design of gradually decreasing the arrangement density of the first exhaust holes K1 along the first direction X is conducive to completely discharging hydrogen gas (H₂) in the inorganic film layer proximate to the display region AA. The closer to the hole-opening region H, the smaller the influence of hydrogen gas (H₂) in the inorganic film layer on the image display. Therefore, first exhaust holes K with a relatively small density may be arranged in a region proximate to the hole-opening region H to achieve a relatively good exhaust effect.

In some embodiments, as shown in FIG. 6, a cross-section of the first exhaust hole K1 is in a shape of any one of a rectangle, a triangle, a pentagon, a hexagon, and a circle. Here, a plane where the cross-section is located is parallel to a plane where the substrate 101 is located.

That is to say, a shape of the first exhaust hole K1 in a direction perpendicular to its axis line may be any one of a rectangle, a triangle, a pentagon, a hexagon, a circle, etc., which is not limited here and may be set as needed.

In some embodiments, as shown in FIG. 5, the display panel 100 further includes: a second semiconductor layer 208 disposed between the second inorganic insulating layer 207 and the third gate insulating layer 209, in the wiring region F1. And the display panel 100 is provided therein with a plurality of second exhaust holes K2 in the wiring region F1, and each second exhaust hole K2 in the plurality of second exhaust holes K2 extends to the second semiconductor layer 208 from the side of the display panel 100 opposite the substrate 101.

For example, the plurality of second exhaust holes K2 are arranged around the hole-opening region H in a loop shape. The provision of the second exhaust holes K2 can discharge hydrogen gas (H₂) in the inorganic film layer in the wiring region F1 to prevent the influence of hydrogen gas (H₂) on the display image quality of the display panel 100.

In some embodiments, as shown in FIG. 5, the display panel 100 is provided therein with a plurality of third exhaust holes K3 in the wiring region F1, each third exhaust hole K3 in the plurality of third exhaust holes K3 penetrates through each silicon nitride layer in the at least one silicon nitride layer, and each third exhaust hole K3 in the plurality of third exhaust holes K3 extends to the first semiconductor layer 202 from the side of the display panel 100 opposite the substrate 101.

For example, the plurality of third exhaust holes K3 are arranged around the hole-opening region H in a loop shape. The provision of the third exhaust holes K3 can discharge hydrogen gas (H₂) in the inorganic film layer in the wiring region F1 to prevent the influence of hydrogen gas (H₂) on the display image quality of the display panel 100.

In some embodiments, as shown in FIG. 6, the display panel 100 includes a first exhaust hole K1, a second exhaust hole K2 (as shown in FIG. 5) and a third exhaust hole K3 (as shown in FIG. 5), and the first exhaust hole K1, the second exhaust hole K2 and the third exhaust hole K3 each have a size U3 in a range of 0.5 μm to 3 μm.

For example, the first exhaust hole K1, the second exhaust hole K2 and the third exhaust hole K3 are all rectangular holes, and the first exhaust hole K1, the second exhaust hole K2 and the third exhaust hole K3 each have a side length in a size U3 of 0.5 μm, 1 μm, 1.5 μm, 2 μm, 2.5 μm, 3 μm, orthe like, which is not limited here. As another example, the first exhaust hole K1, the second exhaust hole K2 and the third exhaust hole K3 are all circular, and the first exhaust hole K1, the second exhaust hole K2 and the third exhaust hole K3 each have a diameter in a size U3 of 0.5 μm, 1 μm, 1.5 μm, 2 μm, 2.5 μm, 3 μm, or the like, which is not limited here.

For example, the first exhaust hole K1, the second exhaust hole K2, and the third exhaust hole K3 are formed by a dry etching process.

In order to further solve the problem of low grayscale brightness unevenness of the display panel 100, the technical solutions of some embodiments of the present disclosure make adjustments to the design of the pixels P.

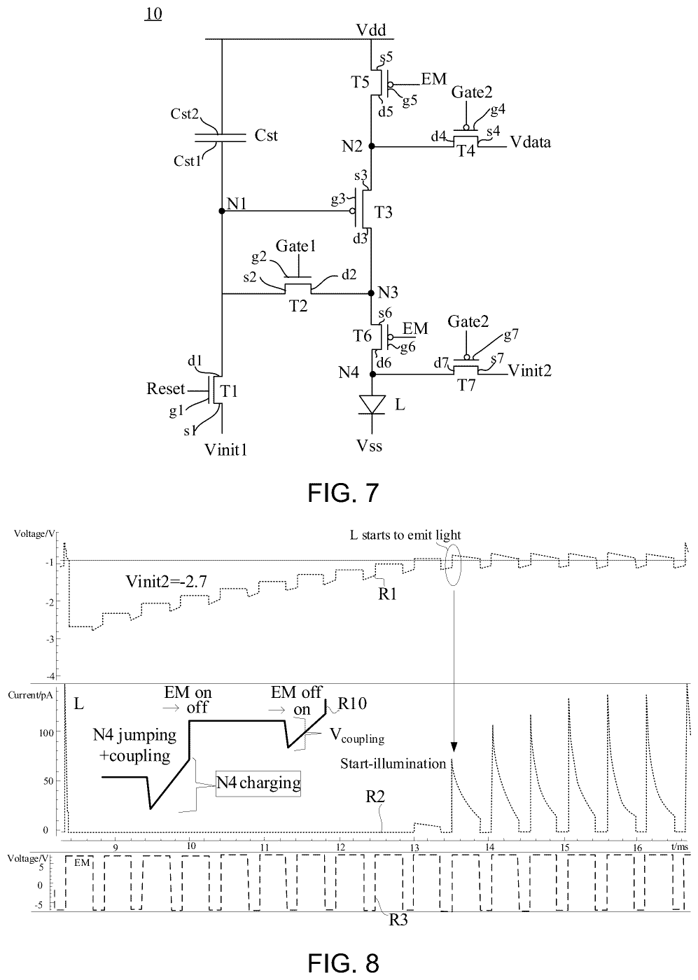

In order to more clearly understand the cause of the problem of low grayscale brightness unevenness of the display panel 100 and the solutions provided by some embodiments of the present disclosure, some embodiments of the present disclosure first introduce a structure of a pixel driving circuit 10 in a display panel 100, and the structure of the pixel driving circuit 10 is shown in FIG. 7. It will be noted that the structure of the pixel driving circuit 10 is only an example of a structure of a pixel driving circuit 10 provided in some embodiments of the present disclosure, and is not a limitation to the structure of the pixel driving circuit 10.

In some examples, as shown in FIG. 7, the pixel driving circuit 10 includes: a first reset transistor T1, a compensation transistor T2, a driving transistor T3, a data writing transistor T4, a first light-emitting control transistor T5, a second light-emitting control transistor T6, and a second reset transistor T7.

For example, the first reset transistor T1 and the compensation transistor T2 may each be an oxide thin film transistor, e.g., a low temperature polycrystalline oxide (LTPO) transistor, which is turned on at a high level; while the driving transistor T3, the data writing transistor T4, the first light-emitting control transistor T5, the second light-emitting control transistor T6, and the second reset transistor T7 are each a low temperature poly-silicon (LTPS) thin film transistor of a P-type, which is turned on at a low level.

For example, as shown in FIG. 7, the first reset transistor T1 includes: a gate g1, a first electrode s1, and a second electrode d1, in which the gate g1 of the first reset transistor T1 is electrically connected to a reset signal terminal, the first electrode s1 of the first reset transistor T1 is electrically connected to a first initial signal terminal, and the second electrode d1 of the first reset transistor T1 is electrically connected to a first node N1. The reset signal terminal is used to receive a reset signal transmitted by a reset signal line Reset. The first initial signal terminal is used to receive a first initial signal transmitted by a first initial signal line Vinit1. The first reset transistor T1 is configured to: transmit the first initial signal received at the first initial signal line Vinit1 to the first node N1 in response to the reset signal received at the reset signal line Reset to reset a gate g3 of the driving transistor T3.

It will be noted that, of a transistor in the present disclosure, a first electrode is one of a source and a drain of the transistor, and a second electrode is the other of the source and the drain of the transistor. Since source and drain of a transistor may be structurally symmetrical, the source and drain thereof may be structurally indistinguishable. That is to say, of the transistor in the embodiments of the present disclosure, the first electrode and the second electrode may be structurally indistinguishable. For example, in a case where the transistor is a P-type transistor, the first electrode of the transistor is a source while the second electrode is a drain; for example, in a case where the transistor is an N-type transistor, the first electrode of the transistor is a drain while the second electrode is a source.

It will be noted that in a circuit provided by the embodiments of the present disclosure, a node does not represent an actual component, but rather represents a junction of related electrical connections in a diagram of the circuit. That is to say, the node is a node that is equivalently formed by the junction of related electrical connections in the circuit diagram.

For example, as shown in FIG. 7, the compensation transistor T2 includes: a gate g2, a first electrode s2, and a second electrode d2, in which the gate g2 of the compensation transistor T2 is electrically connected to a first scanning signal terminal, the first electrode s2 of the compensation transistor T2 is electrically connected to the first node N1, and the second electrode d2 of the compensation transistor T2 is electrically connected to a third node N3. The first scanning signal terminal is used to receive a first scanning signal transmitted by a first scanning signal line Gate1. The compensation transistor T2 is configured to: compensate the driving transistor T3 with a threshold value in response to the first scanning signal received at the first scanning signal line Gate1.

For example, as shown in FIG. 7, the driving transistor T3 includes: a gate g3, a first electrode s3, and a second electrode d3, in which the gate g3 of the driving transistor T3 is electrically coupled to the first node N1, the first electrode s3 of the driving transistor T3 is electrically coupled to a second node N2, and the second electrode d3 of the driving transistor T3 is electrically coupled to the third node N3. The driving transistor T3 is configured to: generate a driving current signal.

For example, as shown in FIG. 7, the data writing transistor T4 includes: a gate g4, a first electrode s4, and a second electrode d4, in which the gate g4 of the data writing transistor T4 is electrically connected to a second scanning signal terminal, the first electrode s4 of the data writing transistor T4 is electrically connected to a data signal terminal, and the second electrode d4 of the data writing transistor T4 is electrically connected to the second node N2. The data signal terminal is used to receive a data signal transmitted by a data signal line Vdata. The data writing transistor T4 is configured to: transmit the data signal received at the data signal line Vdata to the driving transistor T3 in response to the second scanning signal received at the second scanning signal line Gate2.

For example, as shown in FIG. 7, the first light-emitting control transistor T5 includes: a gate g5, a first electrode g5, and a second electrode d5, in which the gate g5 of the first light-emitting control transistor T5 is electrically connected to a light-emitting control signal terminal, the first electrode g5 of the first light-emitting control transistor T5 is electrically connected to a power supply signal terminal, and the second electrode d5 of the first light-emitting control transistor T5 is electrically connected to the second node N2. The light-emitting control signal terminal is used to receive a light-emitting control signal transmitted by a light-emitting control signal line EM. The power supply signal terminal is used to receive a power supply signal transmitted by a power supply signal line Vdd. The first light-emitting control transistor T5 is configured to: transmit the power supply signal received at the power supply signal line Vdd to the driving transistor T3 in response to the light-emitting control signal received at the light-emitting control signal line EM.

For example, as shown in FIG. 7, the second light-emitting control transistor T6 includes: a gate g6, a first electrode s6, and a second electrode d6, in which the gate g6 of the second light-emitting control transistor T6 is electrically coupled to the light-emitting control signal terminal, the first electrode s6 of the second light-emitting control transistor T6 is electrically coupled to the third node N3, and the second electrode d6 of the second light-emitting control transistor T6 is electrically coupled to a fourth node N4. The second light-emitting control transistor T6 is configured to: transmit the driving current signal to a light-emitting device L in response to the light-emitting control signal received at the light-emitting control signal line EM to drive the light-emitting device L to emit light.

For example, as shown in FIG. 7, the second reset transistor T7 includes: a gate g7, a first electrode s7, and a second electrode d7, in which the gate g7 of the second reset transistor T7 is electrically connected to the second scanning signal terminal, the first electrode s7 of the second reset transistor T7 is electrically connected to a second initial signal terminal, and the second electrode d7 of the second reset transistor T7 is electrically connected to the fourth node N4. The second reset transistor T7 is configured to: transmit a second initial signal received at a second initial signal line Vinit2 to the light-emitting device L in response to the second scanning signal received at the second scanning signal line Gate2 to reset the light-emitting device L.

For example, an anode of the light-emitting device L is electrically connected to the fourth node N4, and a cathode of the light-emitting device L is electrically connected to a reference voltage line Vss.

For example, as shown in FIG. 7, the pixel driving circuit 10 further includes: a capacitor Cst. The capacitor Cst includes: a first electrode plate Cst1 and a second electrode plate Cst2, in which the first electrode plate Cst1 of the capacitor Cst is electrically connected to the first node N1, and the second electrode plate Cst2 of the capacitor Cst is electrically connected to the power supply signal terminal.

The above embodiment describes a structure of a 7T1C circuit, and the pixel driving circuit 10 in the embodiments of the present disclosure may also include a 3T1C, 8T1C, or 9T1C circuit, which is not limited here. Here, T represents a transistor, a number preceding T represents a number of transistors, C represents a capacitor, and a number preceding C represents a number of capacitors. By way of example, 7T1C represents 7 transistors and 1 capacitor.

Using the structure of the 7T1C circuit described above as an example, the following describes solutions to the problem of low grayscale brightness unevenness of the display panel 100.

The inventors have found that as shown in FIG. 7 and FIG. 8, low grayscale brightness unevenness is related to a start-illumination speed of the light-emitting device L. The faster the start-illumination speed of the light-emitting device L is, the minor the problem of low grayscale brightness unevenness will be. Therefore, the problem of low grayscale brightness unevenness during image display may be alleviated by increasing the start-illumination speed of the light-emitting device L.

Furthermore, the start-illumination speed of the light-emitting device L may be improved by the following three aspects: (1) improving the efficiency of the light-emitting device L; (2) improving a charging speed of the anode (the fourth node N4) of the light-emitting device L; and (3) improving a jumping amount of the fourth node N4.

For example, as shown in FIG. 8, the start-illumination of the light-emitting device L means that the light-emitting device L starts to emit light, that is, when a voltage of the fourth node N4 reaches a certain value, and a current flowing through the light-emitting device L meets the light-emitting requirements of the light-emitting device L, the light-emitting device L emits light.

Specifically, the relationship between the jumping amount of the fourth node N4 and the start-illumination of the light-emitting device L is shown in FIG. 8. A light-emitting process of the light-emitting device L is actually a charging process of the fourth node N4, where the charging process of the fourth node N4 includes: a charging of the fourth node N4 and the jumping of the fourth node N4.

For example, as shown in FIG. 8, R1 denotes a voltage curve R1 of the fourth node N4 under the condition that a voltage of a signal transmitted by the second initial signal line Vinit2 is −2.7 V. R2 denotes a current curve R2 in which a current flowing through the light-emitting device L varies with the voltage curve R1. R3 denotes a timing line of the light-emitting control signal line EM. R10 is a partially enlarged view of the voltage curve R1, where EM on and EM off indicate the turn-on and turn-off of the second light-emitting control transistor T6, respectively, under the control of the light-emitting control signal transmitted by the light-emitting control signal line EM.

As can be seen from R1 and R10, during the charging process of the fourth node N4, EM on to off causes the voltage of the fourth node N4 to jump to a higher voltage due to a coupling effect, and EM off to on causes the voltage of the fourth node N4 to jump to a lower voltage due to the coupling effect. In the process of EM on to off and EM off to on repeatedly, the voltage of the fourth node N4 can eventually be increased, thereby enabling the light-emitting device L to emit light. Moreover, the voltage of the fourth node N4 after jumping has a decisive effect on the start-illumination voltage of the light-emitting device L, thereby affecting the normal illumination of the light-emitting device L. Therefore, it can be seen that the larger the jumping amount of the fourth node N4 is, the more it facilitates the increase of the start-illumination voltage of the light-emitting device L.

It will be noted that the voltage of the fourth node N4 jumping to a higher voltage means that the voltage value after jumping is higher than the voltage value before the jumping; and the voltage of the fourth node N4 jumping to a lower voltage means that the voltage value after jumping is lower than the voltage value before jumping.

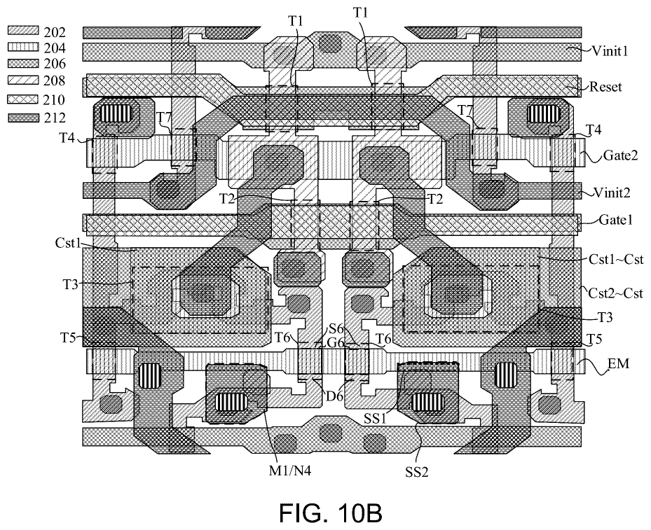

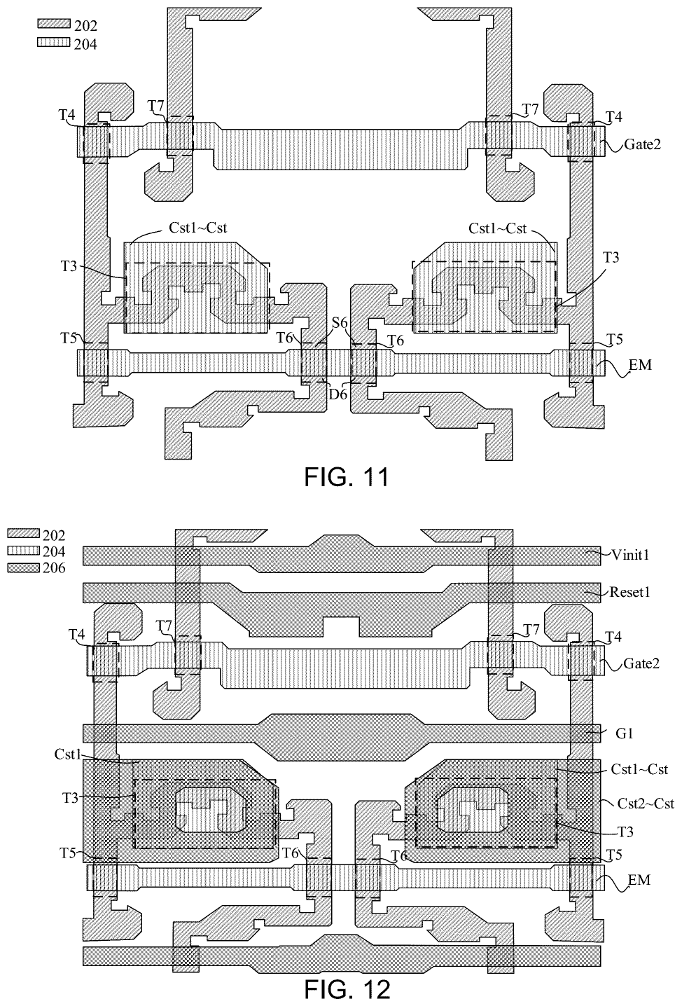

In light of this, in some embodiments provided in the present disclosure, as shown in FIG. 9, the display panel 100 includes: a plurality of pixel driving circuits 10 and a plurality of light-emitting devices L, where a pixel driving circuit 10 in the plurality of pixel driving circuits 10 is used to drive a light-emitting device L in the plurality of light-emitting devices L to emit light. As shown in FIG. 10A and FIG. 11, the pixel driving circuits 10 each include a second light-emitting control transistor T6, and the first semiconductor layer 202 includes a first electrode zone S6 and a second electrode zone D6 of the second light-emitting control transistor T6.

It can be understood that in the first semiconductor layer 202, the first electrode zone S6 of the second light-emitting control transistor T6 corresponds to the first electrode s6 in the pixel driving circuit 10, and the second electrode zone D6 of the second light-emitting control transistor T6 corresponds to the second electrode d6 in the pixel driving circuit 10. It can be also understood that the first electrode zone S6 of the second light-emitting control transistor T6 has the same function as the first electrode s6 of the second light-emitting control transistor T6, and the second electrode zone D6 of the second light-emitting control transistor T6 has the same function as the second electrode d6 of the second light-emitting control transistor T6. The other transistors are understood in the same way and will not be repeated here.

As shown in FIG. 10A, the display panel 100 further includes: a first gate conductive layer 204 disposed on a side of the first semiconductor layer 202 away from the substrate 101 (as shown in FIG. 9, and similarly hereinafter). The first gate conductive layer 204 includes: light-emitting control signal lines EM and a gate pattern G6 of the second light-emitting control transistor T6, where the gate pattern G6 of the second light-emitting control transistor T6 is electrically connected to a light-emitting control signal line EM.

As shown in FIG. 10A, the display panel 100 further includes: a first source-drain metal layer 212 disposed on a side of the first gate conductive layer 204 away from the substrate 101. The first source-drain metal layer 212 includes first patterns M1, where a first pattern M1 is electrically connected to the second electrode zone D6 of the second light-emitting control transistor T6.

It will be noted that as shown in FIG. 9, an insulating layer is provided between functional film layers, and the insulating layer includes the inorganic film layer as described above. The functional film layers include: the first semiconductor layer 202 and the first gate conductive layer 204, and a second gate conductive layer 206, the second semiconductor layer 208, a third gate conductive layer 210, a first source-drain metal layer 212, a second source-drain metal layer 216, and an anode layer 301 as described below. For example, the first pattern M1 and the second electrode zone D6 of the second light-emitting control transistor T6 are connected to each other through a via hole penetrating through an insulating layer between the two.

For example, a material of the insulating layer may include silicon nitride (SiNₓ), silicon oxide (SiOₓ), silicon oxynitride (SiNₓO_{y}), or other suitable materials.

As shown in FIG. 9, the display panel 100 further includes: an anode layer 301 disposed on a side of the first source-drain metal layer 212 away from the substrate 101, and the anode layer 301 includes anode patterns M31 of the light-emitting devices L, where the first pattern M1 is electrically connected to an anode pattern M31.

For example, the first pattern M1 and the anode pattern M31 are connected to each other through a via hole penetrating through an insulating layer between the two.

Here, as shown in FIG. 10A, a ratio of an overlapping area SS1 of an orthographic projection of the first pattern M1 on the substrate 101 and an orthographic projection of the light-emitting control signal line EM on the substrate 101 to an area SS2 of the orthographic projection of the first pattern M1 on the substrate 101 is greater than 10%.

It will be noted that the first pattern M1 is electrically connected to the second electrode zone D6 of the second light-emitting control transistor T6, and the first pattern M1 is electrically connected to the anode pattern M31, so the first pattern M1 has the same function as the fourth node N4 in the pixel driving circuit 10, that is, the first pattern M1 can be understood as the fourth node N4 in the pixel driving circuit 10.

The inventors have found that the magnitude of the jumping amount of the fourth node N4 is determined by the magnitude of parasitic capacitance at the fourth node N4. Here, parasitic means that no capacitance was originally designed here, but since there is always mutual capacitance between wirings, the mutual capacitance may be considered to be parasitic between the wirings, so it is called parasitic capacitance, also known as stray capacitance. The larger the parasitic capacitance at the fourth node N4 is, the larger the jumping amount of the fourth node N4 is. The parasitic capacitance at the fourth node N4 is related to the overlapping area SS1 of the orthographic projections of the first pattern M1 and the light-emitting control signal line EM on the substrate 101, and the larger the overlapping area SS1 of the orthographic projections of the first pattern M1 and the light-emitting control signal line EM on the substrate 101 is, the larger the parasitic capacitance at the fourth node N4 is.

Therefore, in the embodiments of the present disclosure, the ratio of the overlapping area SS1 of the orthographic projections of the first pattern M1 and the light-emitting control signal line EM on the substrate 101 to the area SS2 of the orthographic projection of the first pattern M1 on the substrate 101 is set to be greater than 10% in order to increase the jumping amount of the fourth node N4. By increasing the overlapping area SS1 of the orthographic projections of the first pattern M1 and the light-emitting control signal line EM on the substrate 101, the purpose of increasing the jumping amount of the fourth node N4 is achieved, thereby increasing the start-illumination speed of the light-emitting device L, so as to alleviate the problem of low grayscale brightness unevenness during image display.

For example, in the related art, as shown in FIG. 10B, a ratio of an overlapping area SS1 of an orthographic projection of the first pattern M1 on the substrate 101 and an orthographic projection of the light-emitting control signal line EM on the substrate 101 to an area SS2 of the orthographic projection of the first pattern M1 on the substrate 101 is less than 10%. The smaller the parasitic capacitance at the fourth node N4 is, the smaller the jumping amount of the fourth node N4 is, which makes it easy to cause low grayscale brightness unevenness during image display.

In some embodiments, as shown in FIG. 10A, the ratio of the overlapping area SS1 of the orthographic projections of the first pattern M1 and the light-emitting control signal line EM on the substrate 101 to the area SS2 of the orthographic projection of the first pattern M1 on the substrate 101 is 25%.

By setting the ratio of the overlapping area SS1 of the orthographic projections of the first pattern M1 and the light-emitting control signal line EM on the substrate 101 to the area SS2 of the orthographic projection of the first pattern M1 on the substrate 101 to 25%, the overlapping area SS1 of the orthographic projections of the first pattern M1 and the light-emitting control signal line EM on the substrate 101 may be effectively increased, achieving the purpose of increasing the jumping amount of the fourth node N4, thereby increasing the start-illumination speed of the light-emitting device L, and effectively alleviating the problem of low grayscale brightness unevenness during image display.

In order to more clearly understand the technical solutions provided by the embodiments of the present disclosure for solving the problem of low grayscale brightness unevenness during image display, a design of a film layer structure of a display panel 100 is exemplified below. It will be noted that the design of the film layer structure of the display panel 100 is only an example and is not a limitation to the technical solutions provided by the embodiments of the present disclosure.

In some examples, as shown in FIG. 9, the display panel 100 includes: a first gate insulating layer 201, a first gate conductive layer 204, a second gate insulating layer 203, a second gate conductive layer 206, a first inorganic insulating layer 205, a second inorganic insulating layer 207, a second semiconductor layer 208, a third gate insulating layer 209, a third gate conductive layer 210, an interlayer dielectric layer 211, a first source-drain metal layer 212, a passivation layer 213, a first passivation layer 214, a second source-drain metal layer 216, and a second passivation layer 215, which are stacked on a side of the first semiconductor layer 202 away from the substrate 101 in sequence.

For example, as shown in FIG. 11, the first semiconductor layer 202 includes active layer patterns of the driving transistor T3, the data writing transistor T4, the first light-emitting control transistor T5, the second light-emitting control transistor T6, and the second reset transistor T7.

For example, the transistors each include a first electrode zone and a second electrode zone, and an active layer pattern of a transistor includes a first electrode zone and a second electrode zone of the transistor. For example, the first electrode zone S6 of the second light-emitting control transistor T6 is electrically connected to the second electrode zone of the driving transistor T3. Similarly, in the layout design, a first electrode zone of a transistor corresponds to a first electrode of the transistor in the pixel driving circuit 10, and a second electrode zone of the transistor corresponds to a second electrode of the transistor in the pixel driving circuit 10, which will not be repeated here.

For example, as shown in FIG. 11, the first gate conductive layer 204 includes gate patterns of the driving transistor T3, the data writing transistor T4, the first light-emitting control transistor T5, the second light-emitting control transistor T6, and the second reset transistor T7.

For example, as shown in FIG. 11, the first gate conductive layer 204 further includes: a first electrode plate Cst1 of the capacitor Cst, the second scanning signal line Gate2, and the light-emitting control signal line EM. A gate pattern of the data writing transistor T4 and a gate pattern of the second reset transistor T7 are electrically connected to the second scanning signal line Gate2, and a gate pattern of the first light-emitting control transistor T5 and a gate pattern of the second light-emitting control transistor T6 are electrically connected to the light-emitting control signal line EM.

For example, as shown in FIG. 12, the second gate conductive layer 206 includes: a second electrode plate Cst2 of the capacitor Cst, the first initial signal line Vinit1, a first reset signal sub-line Reset1, and a first scanning signal sub-line G1.

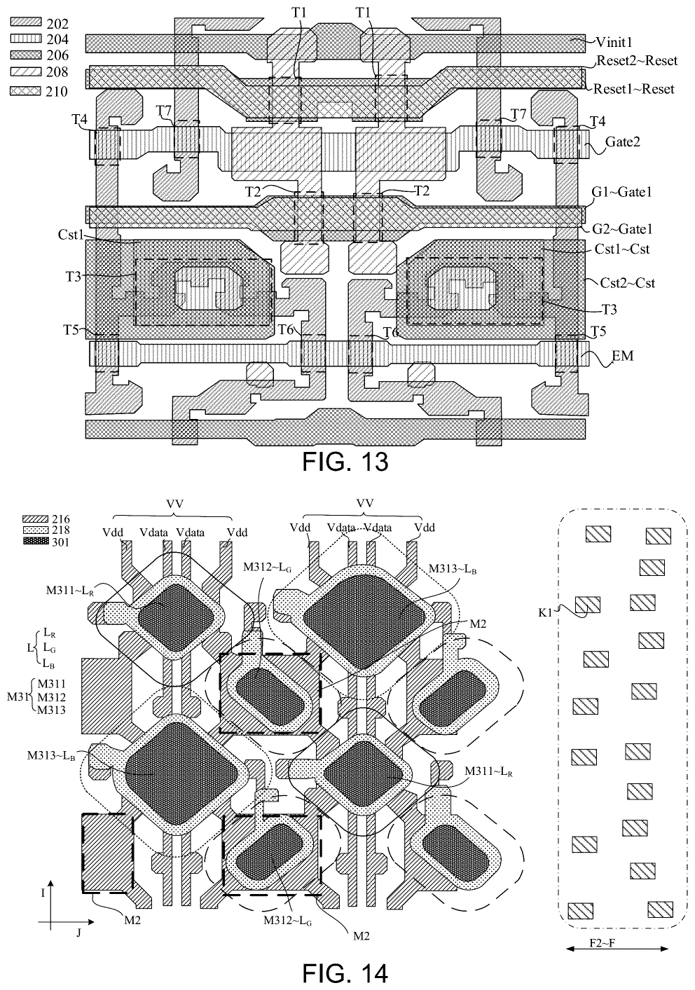

For example, as shown in FIG. 13, the second semiconductor layer 208 includes: active layer patterns of the first reset transistor T1 and the compensation transistor T2.

For example, as shown in FIG. 13, the third gate conductive layer 210 includes: gate patterns of the first reset transistor T1 and the compensation transistor T2.

In some embodiments, as shown in FIG. 13, the third gate conductive layer 210 further includes: a second reset signal sub-line Reset2 and a second scanning signal sub-line G2. Moreover, the second reset signal sub-line Reset2 in the third gate conductive layer 210 and the first reset signal sub-line Reset1 in the second gate conductive layer 206 are electrically connected to each other through a via hole to form the reset signal line Reset; and the second scanning signal sub-line G2 in the third gate conductive layer 210 and the first scanning signal sub-line G1 in the second gate conductive layer 206 are electrically connected to each other through a via hole to form the first scanning signal line Gate1.

A gate pattern of the first reset transistor T1 is electrically connected to the reset signal line Reset, and a gate pattern of the compensation transistor T2 is electrically connected to the first scanning signal line Gate1.

For example, as shown in FIG. 10A, the first source-drain metal layer 212 further includes: the second initial signal line Vinit2.

In some embodiments, as shown in FIG. 10A, a material of the second semiconductor layer 208 includes: indium gallium zinc oxide.

It can be seen from the above content that the start-illumination speed of the light-emitting device L can be improved by increasing the charging speed of the anode (the fourth node N4) of the light-emitting device L. Embodiments of increasing the charging speed of the anode (the fourth node N4) of the light-emitting device L is described below.

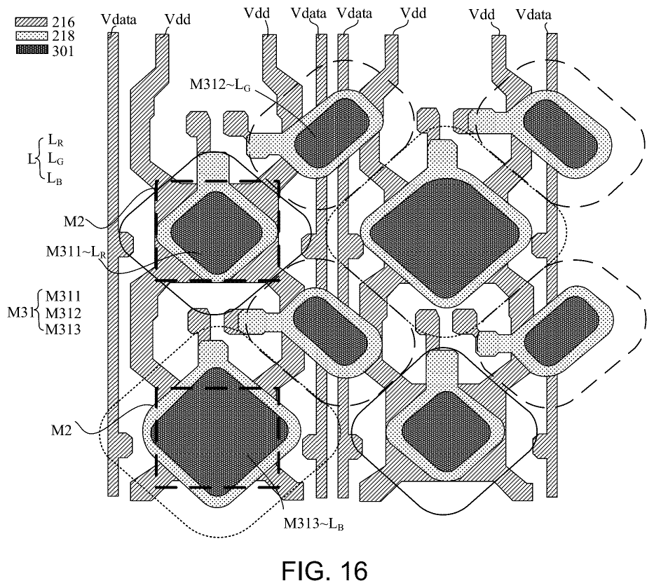

As shown in FIG. 14 and FIG. 16, the display panel 100 includes: a plurality of light-emitting devices L, the plurality of light-emitting devices L including: a plurality of red light-emitting devices L_{R}, a plurality of green light-emitting devices L_{G}, and a plurality of blue light-emitting devices L_{B}. As shown in FIG. 9, the display panel 100 further includes: a second source-drain metal layer 216 disposed on a side of the first semiconductor layer 202 away from the substrate 101, and an anode layer 301 disposed on a side of the second source-drain metal layer 216 away from the substrate 101. As shown in FIG. 14 and FIG. 16, the anode layer 301 includes: a third anode pattern M313 of each blue light-emitting device L_{B} in the plurality of blue light-emitting devices L_{B}.

For example, the anode layer 301 further includes: a first anode pattern M311 of each red light-emitting device L_{R} in the plurality of red light-emitting devices L_{R} and a second anode pattern M312 of each green light-emitting device L_{G} in the plurality of green light-emitting devices L_{G}.

For example, the red light-emitting device L_{R} is configured to emit red light, the green light-emitting device L_{G} is configured to emit green light, and the blue light-emitting device L_{B} is configured to emit blue light, and the provision of the plurality of red light-emitting devices L_{R}, the plurality of green light-emitting devices L_{G}, and the plurality of blue light-emitting devices L_{B} can realize a full-color display of the display panel 100. For example, a pixel P as mentioned above may include: one red light-emitting device L_{R}, two green light-emitting devices L_{G}, and one blue light-emitting device L_{B}.

For example, as shown in FIG. 14 and FIG. 16, a transfer electrode layer 218 may be provided between the second source-drain metal layer 216 and the anode layer 301. The transfer electrode layer 218 includes a plurality of transfer electrodes, and the transfer electrode is used for realizing an electrical connection between each of the anode patterns M31 in the anode layer 301 and a pixel driving circuit 10. Here, the anode patterns M31 include: first anode patterns M311, second anode patterns M312, and third anode patterns M313.

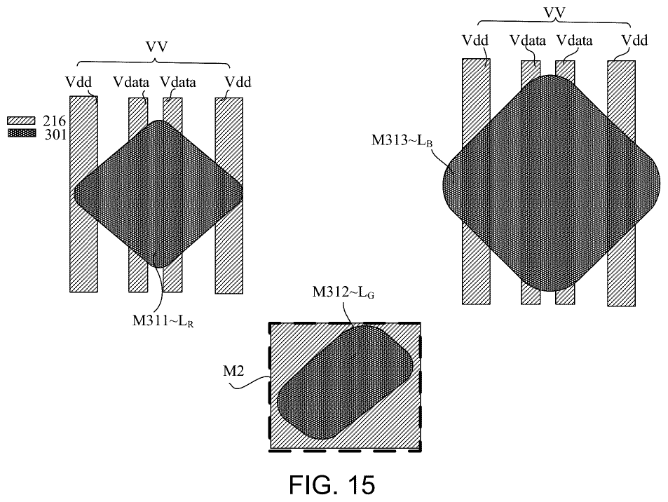

It will be noted that FIG. 14 to FIG. 16 do not show a film layer provided between the second source-drain metal layer 216 and the substrate 101, in order to more clearly show the layout design relationship between the anode layer 301 and the second source-drain metal layer 216, and the film layer provided between the second source-drain metal layer 216 and the substrate 101 can be seen above and will not be repeated herein.

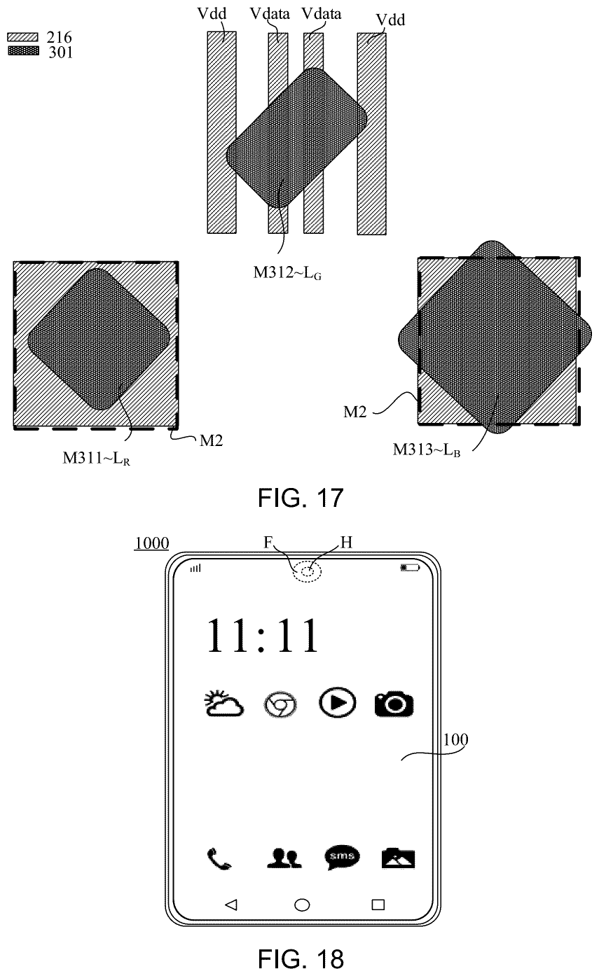

In related art, as shown in FIG. 16 and FIG. 17, the second source-drain metal layer 216 is generally designed with second patterns M2 of a relatively large area, and an orthographic projection of a second pattern M2 on the substrate 101 covers an orthographic projection of a portion of the functional film layer in the pixel driving circuit on the substrate 101, for example, the orthographic projection of the second pattern M2 on the substrate 101 may cover orthographic projections of the active layer patterns of the first reset transistor T1 and the compensation transistor T2 on the substrate 101. The provision of the second pattern M2 is related to the optics and power consumption of the display panel 100, which is conducive to improving the performance of the display panel 100, and the position and connection relationship of the second pattern M2 can be seen in the subsequent contents, and will not be described in detail here.

For example, as shown in FIG. 16 and FIG. 17, in the related art, since an area of an orthographic projection of the third anode pattern M313 of the blue light-emitting device L_{B} on the substrate 101 is significantly greater than an area of an orthographic projection of the first anode pattern M311 on the substrate 101, and is greater than an area of an orthographic projection of the second anode pattern M312 on the substrate 101, the orthographic projection of the third anode pattern M313 of each blue light-emitting device L_{B} on the substrate 101 overlaps with the orthographic projection of the second pattern M2 on the substrate 101. Such a configuration will result in relatively large parasitic capacitance between the third anode pattern M313 of the blue light-emitting device L_{B} and the second source-drain metal layer 216.

However, the inventors have found that reducing the parasitic capacitance between the third anode pattern M313 of the blue light-emitting device L_{B} and the second source-drain metal layer 216 may improve the overall charging speed of the display panel 100 when displaying images, which is conducive to improving the optical performance of the display panel 100.

In light of this, in some embodiments, as shown in FIG. 14, the second source-drain metal layer 216 includes: a plurality of data signal lines Vdata and a plurality of power supply signal lines Vdd, and the plurality of data signal lines Vdata and the plurality of power supply signal lines Vdd each extend in a second direction I.

It will be noted that the plurality of data signal lines Vdata and the plurality of power supply signal lines Vdd each extending in the second direction I means that the data signal lines Vdata and the power supply signal lines Vdd each have a tendency to extend along the second direction I as a whole.

Here, every two data signal lines Vdata in the plurality of data signal lines Vdata are arranged alternately with every two power supply signal lines Vdd in the plurality of power supply signal lines Vdd along a third direction J, where the second direction I intersects the third direction J.

For example, the second direction I and the third direction J are perpendicular to each other.

A power supply signal line Vdd, a data signal line Vdata, another data signal line Vdata, and another power supply signal line Vdd are arranged in sequence in the third direction J as a signal line group VV. An orthographic projection of a third anode pattern M313 on the substrate 101 overlaps with an orthographic projection of the signal line group VV on the substrate 101.

As shown in FIG. 14, since every two data signal lines Vdata are alternately arranged with every two power supply signal lines Vdd, two data signal lines Vdata and two power supply signal lines Vdd on both sides of the two data signal lines Vdata along the third direction J are categorized into a signal line group VV.

In the related art, since the area of the orthographic projection of the third anode pattern M313 of the blue light-emitting device L_{B} on the substrate 101 is significantly greater than the area of the orthographic projection of the first anode pattern M311 on the substrate 101, and is greater than the area of the orthographic projection of the second anode pattern M312 on the substrate 101, the orthographic projection of the third anode pattern M313 of each blue light-emitting device L_{B} on the substrate 101 overlaps with the orthographic projection of the second pattern M2 on the substrate 101. Such the configuration will result in relatively large parasitic capacitance between the third anode pattern M313 of the blue light-emitting device L_{B} and the second source-drain metal layer 216. The relatively large parasitic capacitance between the third anode pattern M313 of the blue light-emitting device L_{B} and the second source-drain metal layer 216 is not conducive to increasing the charging speed of the display panel 100.

In the layout design of the anode layer 301, the arrangement of overlapping of orthographic projections of a third anode pattern M313 and a signal line group VV on the substrate 101 may reduce the parasitic capacitance between the third anode pattern M313 of a blue light-emitting device L_{B} and the second source-drain metal layer 216, thereby achieving the purpose of increasing the charging speed of the blue light-emitting device L_{B}, and thereby increasing the overall charging speed of the display panel 100 when displaying images, which is beneficial to improving the optical performance of the display panel 100.

Therefore, the technical solutions provided in the above embodiments avoids the arrangement in which an orthographic projection of a third anode pattern M313 of a blue light-emitting device L_{B} on the substrate 101 overlaps with an orthographic projection of a second pattern M2 on the substrate 101, thereby reducing parasitic capacitance between the third anode pattern M313 of the blue light-emitting device L_{B} and the second source-drain metal layer 216.

In some embodiments, as shown in FIG. 14, a ratio of an area of an orthographic projection of the first anode pattern M311 on the substrate 101, an area of an orthographic projection of the second anode pattern M312 on the substrate 101, and an area of an orthographic projection of the third anode pattern M313 on the substrate 101 is 30:21:70. A ratio of an overlapping area of orthographic projections of the first anode pattern M311 and the second source-drain metal layer 216 on the substrate 101, an overlapping area of orthographic projections of the second anode pattern M312 and the second source-drain metal layer 216 on the substrate 101, and an overlapping area of orthographic projections of the third anode pattern M313 and the second source-drain metal layer 216 on the substrate 101 is 14:11:27.

For example, by setting the ratio of the areas of the orthographic projections of the first anode pattern M311, the second anode pattern M312, and the third anode pattern M313 on the substrate 101 to be 30:21:70, and setting the ratio of the overlapping area of the orthographic projections of the first anode pattern M311 and the second source-drain metal layer 216 on the substrate 101, the overlapping area of the orthographic projections of the second anode pattern M312 and the second source-drain metal layer 216 on the substrate 101, and the overlapping area of the orthographic projections of the third anode pattern M313 and the second source-drain metal layer 216 on the substrate 101 to be 14:11:27, a rationalized layout of the first anode pattern M311, the second anode pattern M312, and the third anode pattern M313 is realized, thereby achieving the purpose of solving the problem of uneven display at low grayscale brightness and improving the quality of image display.

By setting the ratio of the overlapping area of the orthographic projections of the first anode pattern M311 and the second source-drain metal layer 216 on the substrate 101, the overlapping area of the orthographic projections of the second anode pattern M312 and the second source-drain metal layer 216 on the substrate 101, and the overlapping area of the orthographic projections of the third anode pattern M313 and the second source-drain metal layer 216 on the substrate 101 to be 14:11:27, as shown in FIG. 14, the parasitic capacitance between the third anode pattern M313 of the blue light-emitting device L_{B} and the second source-drain metal layer 216 may be effectively reduced, the charging speed of the blue light-emitting device L_{B} may be increased, the image display performance of the display panel 100 may be improved, and the problem of uneven display at low grayscale brightness during image display may be effectively solved.

In order to improve the charging speed of the blue light-emitting device L_{B}, the overall layout design of the anode layer 301 needs to be adjusted to reduce the parasitic capacitance between the third anode pattern M313 of the blue light-emitting device L_{B} and the second source-drain metal layer 216. Embodiments of adjusting the layout design of the anode layer 301 are described below.

In some embodiments, as shown in FIG. 14, two adjacent power supply signal lines Vdd in two adjacent signal line groups VV are connected between a plurality of second patterns M2, and an orthographic projection of a second anode pattern M312 on the substrate 101 overlays an orthographic projection of a second pattern M2 of the plurality of second patterns M2 on the substrate 101.

It can be understood that the two adjacent power supply signal lines Vdd here refer to two power supply signal lines Vdd that are provided without a data signal line Vdata therebetween. That is to say, of the two adjacent two power supply signal lines Vdd, one power supply signal line Vdd is located in a signal line group VV, and the other one is located in another signal line group VV adjacent thereto.

For example, as shown in FIG. 14, two adjacent power supply signal lines Vdd are connected to a second pattern M2 formed with a relatively large area, so that the same voltage signal is transmitted between the second pattern M2 and the power supply signal lines Vdd. The design of the second pattern M2 is related to the optics and power consumption of the display panel 100, and is beneficial to improving the performance of the display panel 100.

An orthographic projection of a second anode pattern M312 of a green light-emitting device L_{G} on the substrate 101 overlaps with an orthographic projection of a second pattern M2 on the substrate 101. That is, the second anode pattern M312 is arranged on the second pattern M2 during the film layer stacking process.

In some embodiments, as shown in FIG. 14, an orthographic projection of a first anode pattern M311 on the substrate 101 overlaps with an orthographic projection of a signal line group VV on the substrate 101.

That is, by stacking a first anode pattern M311 and a third anode pattern M313 on a signal line group W, and arranging a second anode pattern M312 on a second pattern M2, a rationalized design of the first anode pattern M311, the second anode pattern M312, and the third anode pattern M313 is realized to achieve a design in which the ratio of the overlapping area of the orthographic projections of the first anode pattern M311 and the second source-drain metal layer 216 on the substrate 101, the overlapping area of the orthographic projections of the second anode pattern M312 and the second source-drain metal layer 216 on the substrate 101, and the overlapping area of the orthographic projections of the third anode pattern M313 and the second source-drain metal layer 216 on the substrate 101 is 14:11:27.

For example, as shown in FIG. 14, the first anode pattern M311 and the third anode pattern M313 are arranged alternately in the third direction J.

For example, as shown in FIG. 14, by arranging the first anode pattern M311 and the third anode pattern M313 alternately in the third direction J, and arranging the second anode pattern M312 on the second pattern M2, the first anode pattern M311, the second anode pattern M312 and the third anode pattern M313 are arranged in a regular array.

For example, a relative position of the anode layer 301 and the second source-drain metal layer 216 may be adjusted during a process of forming the anode layer 301, so as to realize the design in which the ratio of the overlapping area of the orthographic projections of the first anode pattern M311 and the second source-drain metal layer 216 on the substrate 101, the overlapping area of the orthographic projections of the second anode pattern M312 and the second source-drain metal layer 216 on the substrate 101, and the overlapping area of the orthographic projections of the third anode pattern M313 and the second source-drain metal layer 216 on the substrate 101 is 14:11:27.

For example, in the related art, as shown in FIG. 16, first anode patterns M311, second anode patterns M312, and third anode patterns M313 are arranged in an array, in which an orthographic projection of a first anode pattern M311 on the substrate 101 overlaps with an orthographic projection of a second pattern M2 on the substrate 101, and an orthographic projection of a third anode pattern M313 on the substrate 101 overlaps with an orthographic projection of another second pattern M2 on the substrate 101. The area of the orthographic projection of the third anode pattern M313 of the blue light-emitting device L_{B} on the substrate 101 is significantly greater than the area of the orthographic projection of the first anode pattern M311 on the substrate 101, and is greater than the area of the orthographic projection of the second anode pattern M312 on the substrate 101. In this case, the third anode pattern M313 of the blue light-emitting device L_{B} and the second source-drain metal layer 216 have relatively large parasitic capacitance therebetween.

Comparing FIG. 14 with FIG. 16, it can be seen that an overall arrangement of the array configuration of the first anode patterns M311, the second anode patterns M312, and the third anode patterns M313 remains unchanged. By adjusting the relative positional relationship between the anode layer 301 and the second source-drain metal layer 216, it can be realized to adjust the magnitude of an overlapping area of an orthographic projection of each of the first anode pattern M311, the second anode pattern M312, and the third anode pattern M313 on the substrate 101 and the orthographic projection of the second source-drain metal layer 216 on the substrate 101.

For example, by the overall movement design of the first anode pattern M311, the second anode pattern M312, and the third anode pattern M313 arranged in an array, as shown in FIG. 14, it is possible to achieve a design in which the orthographic projection of the second anode pattern M312 of the adjusted green light-emitting device L_{G} on the substrate 101 overlaps with the orthographic projection of the second pattern M2 on the substrate. In this case, the relative position of the anode layer 301 and the second source-drain metal layer 216 is changed.

As shown in FIG. 14, in the process of adjusting the layout design of the anode layer 301, the light-emitting devices L will relatively approach the hole-edge region F, causing bright spots to appear around the hole-opening region H, resulting in uneven brightness of image display. In this case, it is necessary to arrange the plurality of first exhaust holes K1 in the encapsulation region F2 of the hole-edge region F to solve the problem of bright spots around the hole-opening region H. The description of the provision of the exhaust holes in the hole-edge region F can be found specifically in the above content and will not be repeated here.

In another aspect, as shown in FIG. 18, some embodiments of the present disclosure further provide a display apparatus 1000, the display apparatus 1000 including the display panel 100 as described in any of the above embodiments.

In some examples, the display apparatus 1000 further includes a frame, a circuit board, a display driving IC (Integrated Circuit), and other electronic accessories, where the display panel 100 is disposed within the frame.

The display apparatus provided in the present disclosure may be any apparatus that can display images whether in motion (e.g., videos) or stationary (e.g., still images) and whether text or images. More specifically, it is expected that the embodiments may be implemented in or associated with a plurality of electronic devices. The plurality of electronic devices may include (but are not limited to), for example, mobile telephones, wireless devices, personal data assistants (PDA), hand-held or portable computers, GPS receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry) etc.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising: a display region, at least one hole-opening region, and a hole-edge region between a hole-opening region in the at least one hole-opening region and the display region, the hole-edge region surrounding the hole-opening region;
wherein the hole-edge region includes: a wiring region and an encapsulation region arranged in sequence along a first direction, the first direction being a direction from the display region to the hole-opening region; and
the display panel further comprises: a substrate, and a first semiconductor layer and at least one silicon nitride layer that are arranged in a stack on the substrate in sequence;
wherein the display panel is provided therein with a plurality of first exhaust holes in the encapsulation region, each first exhaust hole in the plurality of first exhaust holes penetrates through each silicon nitride layer in the at least one silicon nitride layer, and each first exhaust hole in the plurality of first exhaust holes extends to the first semiconductor layer from a side of the display panel opposite the substrate.

2. The display panel according to claim 1, wherein the plurality of first exhaust holes are arranged at intervals around the hole-opening region.

3. The display panel according to claim 1, wherein an arrangement density of the plurality of first exhaust holes gradually decreases along the first direction.

4. The display panel according to claim 1, wherein a cross-section of the first exhaust hole is in a shape of any one of a rectangle, a triangle, a pentagon, a hexagon, and a circle, a plane where the cross-section is located being parallel to a plane where the substrate is located.

5. The display panel according to claim 1, further comprising: a first gate insulating layer, a second gate insulating layer, a first inorganic insulating layer, a second inorganic insulating layer, a third gate insulating layer, an interlayer dielectric layer, and a passivation layer that are disposed on a side of the first semiconductor layer away from the substrate;
wherein the at least one silicon nitride layer includes: the second gate insulating layer, the first inorganic insulating layer and the passivation layer; and the first exhaust hole penetrates through the passivation layer, the interlayer dielectric layer, the third gate insulating layer, the second inorganic insulating layer, the first inorganic insulating layer, the second gate insulating layer, and the first gate insulating layer.

6. The display panel according to claim 5, further comprising: a second semiconductor layer disposed between the second inorganic insulating layer and the third gate insulating layer, in the wiring region;
wherein the display panel is provided therein with a plurality of second exhaust holes in the wiring region, and each second exhaust hole in the plurality of second exhaust holes extends to the second semiconductor layer from the side of the display panel opposite the substrate.

7. The display panel according to claim 1, wherein the display panel is provided therein with a plurality of third exhaust holes in the wiring region, each third exhaust hole in the plurality of third exhaust holes penetrates through each silicon nitride layer in the at least one silicon nitride layer, and each third exhaust hole in the plurality of third exhaust holes extends to the first semiconductor layer from the side of the display panel opposite the substrate.

8. The display panel according to claim 1, wherein the display panel comprises: the first exhaust hole, and further comprises a second exhaust hole and a third exhaust hole, and the first exhaust hole, the second exhaust hole and the third exhaust hole each have a size in a range of 0.5 μm to 3 μm.

9. The display panel according to claim 1,
further comprising: a plurality of pixel driving circuits and a plurality of light-emitting devices, wherein a pixel driving circuit in the plurality of pixel driving circuits is used to drive a light-emitting device in the plurality of light-emitting devices to emit light, the plurality of pixel driving circuits each include a second light-emitting control transistor, and the first semiconductor layer includes a first electrode zone and a second electrode zone of the second light-emitting control transistor;
further comprising: a first gate conductive layer disposed on a side of the first semiconductor layer away from the substrate, wherein the first gate conductive layer includes: a plurality of light-emitting control signal lines and a gate pattern of the second light-emitting control transistor, and the gate pattern of the second light-emitting control transistor is electrically connected to a light-emitting control signal line in the plurality of light-emitting control signal lines;
further comprising: a first source-drain metal layer disposed on a side of the first gate conductive layer away from the substrate, wherein the first source-drain metal layer includes a plurality of first patterns, and a first pattern in the plurality of first patterns is electrically connected to the second electrode zone of the second light-emitting control transistor; and
further comprising: an anode layer disposed on a side of the first source-drain metal layer away from the substrate, wherein the anode layer includes anode patterns of the plurality of light-emitting devices, and the first pattern is electrically connected to an anode pattern of a light-emitting device in the plurality of light-emitting devices;
wherein a ratio of an overlapping area of an orthographic projection of the first pattern on the substrate and an orthographic projection of the light-emitting control signal line on the substrate to an area of the orthographic projection of the first pattern on the substrate is greater than 10%.

10. The display panel according to claim 9, wherein the ratio of the overlapping area of the orthographic projection of the first pattern on the substrate and the orthographic projection of the light-emitting control signal line on the substrate to the area of the orthographic projection of the first pattern on the substrate is 25%.

11. The display panel according to claim 1, further comprising: a plurality of light-emitting devices, the plurality of light-emitting devices including: a plurality of red light-emitting devices, a plurality of green light-emitting devices and a plurality of blue light-emitting devices; and
further comprising: a second source-drain metal layer disposed on a side of the first semiconductor layer away from the substrate, wherein the second source-drain metal layer includes: a plurality of data signal lines and a plurality of power supply signal lines, and the plurality of data signal lines and the plurality of power supply signal lines each extend in a second direction;
wherein every two data signal lines in the plurality of data signal lines are arranged alternately with every two power supply signal lines in the plurality of power supply signal lines along a third direction, the second direction intersecting the third direction; and
in the plurality of data signal lines and the plurality of power supply signal lines, a power supply signal line, a data signal line, another data signal line, and another power supply signal line are arranged in sequence in the third direction as a signal line group; and
the display panel further comprises: an anode layer disposed on a side of the second source-drain metal layer away from the substrate, wherein the anode layer includes: a third anode pattern of each blue light-emitting device in the plurality of blue light-emitting devices, and an orthographic projection of the third anode pattern on the substrate overlaps with an orthographic projection of the signal line group on the substrate.

12. The display panel according to claim 11, wherein the anode layer further includes: a first anode pattern of each red light-emitting device in the plurality of red light-emitting devices and a second anode pattern of each green light-emitting device in the plurality of green light-emitting devices;
wherein a ratio of an area of an orthographic projection of the first anode pattern on the substrate, an area of an orthographic projection of the second anode pattern on the substrate, and an area of an orthographic projection of the third anode pattern on the substrate is 30:21:70; and a ratio of an overlapping area of orthographic projections of the first anode pattern and the second source-drain metal layer on the substrate, an overlapping area of orthographic projections of the second anode pattern and the second source-drain metal layer on the substrate, and an overlapping area of orthographic projections of the third anode pattern and the second source-drain metal layer on the substrate is 14:11:27.

13. The display panel according to claim 12, wherein the second source-drain metal laver further includes: a plurality of second patterns connected between two adjacent power supply signal lines in two adjacent signal line groups, and the orthographic projection of the second anode pattern on the substrate overlaps with an orthographic projection of a second pattern in the plurality of second patterns on the substrate.

14. The display panel according to claim 12, wherein the orthographic projection of the first anode pattern on the substrate overlaps with the orthographic projection of the signal line group on the substrate.

15. The display panel according to claim 1, further comprising a plurality of pixel driving circuits, each pixel driving circuit in the plurality of pixel driving circuits including: a first reset transistor, a compensation transistor, a driving transistor, a data writing transistor, a first light-emitting control transistor, a second light-emitting control transistor, and a second reset transistor;
wherein the first reset transistor and the compensation transistor each include an oxide thin film transistor; and the driving transistor, the data writing transistor, the first light-emitting control transistor, the second light-emitting control transistor, and the second reset transistor each include a low temperature polycrystalline silicon thin film transistor.

16. A display apparatus, comprising the display panel according to claim 1.

17. The display panel according to claim 3, wherein in a direction perpendicular to the first direction, there is a first distance between two adjacent first exhaust holes in the plurality of first exhaust holes; and
in the direction perpendicular to the first direction, there is a second distance between another two adjacent first exhaust holes in the plurality of first exhaust holes further away from the hole-opening region as compared to the two adjacent first exhaust holes;
wherein the first distance is greater than the second distance.

18. The display panel according to claim 6, wherein the second exhaust hole penetrates through the passivation layer, the interlayer dielectric layer and the third gate insulating layer.

19. The display panel according to claim 9, further comprising:
a second source-drain metal layer disposed on a side of the first semiconductor layer away from the substrate; and
a transfer electrode layer disposed between the second source-drain metal layer and the anode layer, the transfer electrode layer including a plurality of transfer electrodes, wherein the pixel driving circuit is electrically connected to the anode pattern through a transfer electrode in the plurality of transfer electrodes.

20. The display panel according to claim 12, wherein the first anode pattern and the third anode pattern are arranged alternately in the third direction.
